(19) United States
(12) Patent Application Publication
(10) Pub. No.: US 2012/0283970 A1
(43) Pub. Date: Nov. 8, 2012

(54) Method and device for error-compensated current measurement of an electrical accumulator

(76) Inventor: Andre Boehm, Kornwestheim (DE)

(21) Appl. No.: 13/510,682

(22) PCT Filed: Nov. 19, 2009
(86) PCT No.: PCT/EP09/65474

§ 371 Date: Jul. 26, 2012

(51) Int. Cl. G01R 19/32

(52) U.S. Cl. 702/64

(57) ABSTRACT

A method for error-compensated current measurement of an electrical accumulator, including: providing a time window-related estimated charge ascertained by a model-based estimator from operating variables of the accumulator and reflecting the estimated charge that has been withdrawn from the accumulator and supplied to the accumulator within the time window; and detecting the accumulator current supplied to the accumulator and withdrawn from the accumulator during the time window, with a current detection sensor. A zero crossing point in time (estimated charge is essentially zero) and a maximum point in time (the absolute value of the estimated charge essentially has a relative maximum or has a value which is greater than a minimum charge difference) are detected. A current measurement offset error is ascertained at the zero crossing point in time by comparing the estimated charge to the detected accumulator current. The accumulator current is ascertained according to the current measurement offset error, and a current measurement scaling error is ascertained at the maximum point in time by comparing the estimated charge to the detected accumulator current. The ascertained current measurement offset error is subtracted from the comparison result thus obtained, and the accumulator current is compensated for based on the current measurement scaling error. A related device for error-compensated current measurement is also described.

### FIELD OF THE INVENTION

The present invention is directed to a method for compensating for errors in current measurements, in particular current measurements for ascertaining a state of charge of an electrical accumulator which is used as a store for traction power of a motor vehicle.

### BACKGROUND INFORMATION

For measuring current, current sensors, for example so-called shunt resistors, through which the current to be measured flows, or magnetic sensors for detecting the magnetic field generated by the current, are used. Based on the drop in voltage, the current which flows through may be deduced with the aid of the resistance value. The dropping voltage at the shunt resistor is preprocessed by (high-impedance) measuring amplifiers or buffer stages, and in the case of digital further processing is transmitted to an analog/digital converter. The analog/digital converter uses a voltage reference for the conversion.

In particular changes in temperature, as well as other influences such as irradiation or variation in operating voltages, result not only in tolerance errors, but also additional errors in such a measuring setup. In particular when the detected current is integrated in order to deduce a charge quantity which has flowed through, the error portion is also integrated. Known measures for reducing such errors include complicated temperature compensation circuits, high-precision resistors as shunt resistors, or high-precision reference voltage sources for the analog/digital converter, as well as precise measuring transducers for preprocessing the analog voltage signal. All of these measures involve high component costs, and also require individual calibration of each measuring circuit. In particular, high-precision shunt resistors in high-current applications, in the automotive field, for example, result in significant costs. In addition, shunt resistors having high resistance values, which are used for increasing the dropping voltage in order to increase the measuring accuracy, result in undesirably high power losses, which, among other things, cause self-induced temperature drift due to the heating during the measurement.

All errors in the measuring circuit are uncorrelated with one another, and are therefore additive. Since in such measuring devices, which are currently multilevel devices (shunt resistor-buffer stage-sample-and-hold stage-A/D converter-microcontroller), a high error rate results which may be compensated for only by expensive, high-precision components, it is an object of the exemplary embodiments and/or exemplary methods of the present invention to provide a method and a device for error-compensated current measurement which results in high precision, even for time integration of the measured current values.

### SUMMARY OF THE INVENTION

The exemplary embodiments and/or exemplary methods of the present invention are intended to allow the use of inexpensive components, for example having high manufacturing tolerances, without resulting in a high measuring error. In particular, the exemplary embodiments and/or exemplary methods of the present invention are intended to allow high measuring accuracies to be achieved without the need for individual calibrations of individual circuits, for example to compensate for manufacturing tolerances. In particular, the current measurement according to the present invention allows a considerable increase in the accuracy of state of charge estimations which relate to the accumulator. Such estimations are based, among other things, on a current measurement with the aid of a shunt, the current values being integrated, which results in additive errors. Such state of charge estimations, also referred to as SOC estimations, are necessary in particular for ascertaining the remaining range of motor vehicles in which an electrical accumulator provides (at least part of) the traction power.

The exemplary embodiments and/or exemplary methods of the present invention are believed to be suited in particular for current measurement of electrical accumulators in which electrical traction power of a motor vehicle is stored, for example for accumulators of a hybrid drive or an electric drive of a passenger vehicle, a utility vehicle, or other motor vehicles. Moreover, the exemplary embodiments and/or exemplary methods of the present invention relate to a state of charge estimation for an accumulator with the aid of an integrated measured current or an estimated state of charge, detection errors of the measured current being at least partially compensated for by the method according to the present invention.

An underlying aspect of the exemplary embodiments and/or exemplary methods of the present invention is to use an estimator for charges, in addition to current estimation based on the measurement by a shunt resistor or some other current sensor. The estimations relate to a charge quantity which is supplied to the accumulator or withdrawn from same during a predetermined time interval, i.e., within a time window.

Because such a charge relates to a time window, the charge also has a current-related aspect, since, due to the time window, the charge is normalized to same, and therefore essentially represents a current (an average value or an integral of a current over the time window). According to an aspect underlying the present invention, the estimation of the relative charge is based not only on the measured current, but also on a variable which results not directly, but, rather, indirectly, from the current, for example via a model (or an interpolation).

In relation to the accumulator, the estimator is thus based on a model which represents the physical characteristics of the accumulator, the model simulation being based not only on the accumulator current, but also on variables which are only indirectly, or not dependent on same, such as terminal voltage, no-load voltage, or accumulator temperature, which represent operating variables on which the state of the accumulator or the state of charge of the accumulator is dependent. Thus, according to the exemplary embodiments and/or exemplary methods of the present invention, an accumulator model of the estimator is considered which relates the relative charge to the model, which is defined by further operating parameters, and the operating parameters, in addition to the accumulator current, and other operating variables for ascertaining the state of the battery being taken into account. Thus, besides the measured accumulator current, the terminal voltage and the temperature of the accumulator are physical measuring variables which are included in the state determination by the model, with the aid of the estimator.

The exemplary embodiments and/or exemplary methods of the present invention is believed to be suited in particular for detecting the state of charge (SOC) of the accumulator, in that the error-compensated current according to the present invention is integrated, and/or the estimator estimates and outputs not only the relative charge but also the state of charge, among other things, based on the error-compensated current. According to the exemplary embodiments and/or exemplary methods of the present invention, the SOC estimator has two functions: estimating the state of charge, on the one hand, and estimating the time window-related relative charge, on the other hand, in order to determine one (or multiple) calibration points for the current measurement (by the current sensor), and thus, an estimated flowed relative charge. The function of detecting the calibration points in time/error detection points in time may also be predefined by comparing the absolute value of the measured current, its average value, or its time window-related integral, to a minimum value (offset error detection) and to a maximum value (scaling error detection).

The calibration values result from comparing the measured current to the estimated relative charge. The estimator not only determines the calibration points on the basis of time, but also specifies a relative charge for a time window, on the basis of which the current measurement is calibrated. As previously described, the calibration is carried out according to the present invention by ascertaining the offset error and the scaling error. The scaling error is ascertained based on the ascertained offset error and based on a further measurement and an associated relative charge supplied by the estimator. The relative charge relates to a time window which is to be suitably determined by the method.

The time window may be determined, for example, by detecting a suitable measured current value or an estimated relative charge; according to a first specific embodiment, the time window for the scaling error detection is started when there are high measured current values or high estimated relative charges. According to a second specific embodiment, the time window for the scaling error detection is started when the preceding time window ends. If conditions appear during the time window which are unfavorable for the scaling error detection (temporary low accumulator load, ascertained based on the measured current or the estimated relative charge), the time window may be excluded from the scaling error detection in retrospect, and the values ascertained in this regard are then discarded. For detecting the offset error, the time window may likewise be started when the preceding time window ends. For detecting the offset error, it is not absolutely necessary to detect instantaneous values of the current or instantaneous charge values, if it is ensured that over the entire time window the measured current, the integral of the current or the relative charge related to the time window has a small value, i.e., is less than a maximum value or is essentially zero. The associated ending of the time window used for the offset error detection depends in particular on the integral of the measured current or the relative charge associated with the time window, whose values should be less than a maximum value or essentially zero. Thus, the time window may be continued until the integral of the measured current or the associated estimated relative charge is essentially zero, has a zero crossing, or is less than the maximum value. Optionally, the time window may be excluded from the detection of the offset error (i.e., discarded) if, despite a low value of the integral or of the relative charge, the measured current was above a current threshold value at a point in time within the time window which corresponds to a high load (for example, in the range of a standard current load or a maximum current load of the accumulator). Scaling error influences on the offset error detection are thus reduced.

The time window is ended when (i) for the scaling error detection, the duration of considering the current value or the relative charge is regarded as suitable, or when (ii) for the offset error detection, the current value or the relative charge has suitable values, i.e., a suitable curve. Suited in particular for detecting the offset error are time windows of a low accumulator load, in which the relative charge, the measured current, or its integral related to the started time window is approximately zero, which have a zero crossing or which are less than a maximum value (which may be for the entire time window), as well as time windows in which the integral of the measured current or the estimated relative charge related to the time window is essentially zero or is less than a maximum value. Suitable for detecting the scaling error are time windows of a high accumulator load in which the relative charge or the measured current has a (relative) maximum and/or a minimum value, which may be for the entire time window. The time window for detecting the scaling error may be short, i.e., shorter than the time window for the offset error detection, for example ≦2 min, ≦1 min, ≦30 sec, ≦20 sec, ≦10 sec, ≦5 sec, or ≦2 sec. As a result of the shortness of the time window for the scaling error detection, the error to be summed which results from a remaining offset error is reduced. Instead of the measured current, its time integral over the time window may be used.

For detecting the offset error, time windows are generally used in which the integrated measured accumulator current or the estimated relative charge is less than a maximum value or is essentially zero. In principle, the time window may be set with respect to the start and end after the measured current and the estimated charge are detected, so that for the offset error detection, time windows are generated which have a small integrated accumulator current (or an integrated accumulator current which is essentially zero), and for the scaling error detection, (short) time windows are generated which have a measured current or an estimated relative charge whose value for the entire time window is greater than a minimum value. This may also be achieved in retrospect without defining the time window, in that the time window is suitably ended when the particular condition regarding the integrated accumulator current, the estimated relative charge, or also the duration of the time window (for the scaling error detection) is met. Unsuitable time windows may be discarded, for example when an excessively low value of the measured current is detected during the scaling error detection. The ascertained errors are factored out from the error of the current measurement (or also of the estimated accumulator state) by subtraction (offset error), or multiplication by a compensation factor (scaling error).

SOC estimators which are based on a physical model of the accumulator are known from the related art, as well as the combination of such estimators with a current measurement and a current integration, which is based on a shunt resistor. Such a combination is described, for example, in the patent application DE 102008041300.3 filed Aug. 18, 2008.

According to the exemplary embodiments and/or exemplary methods of the present invention, the estimator is used to estimate a charge quantity related to a time window, the estimation being a function not only of the measured accumulator current, but also of the terminal voltage, the temperature, or a combination thereof, or of further operating parameters of the accumulator. Another approach relevant for the present invention is the subdivision of the current measuring error to be compensated for into an offset error and a scaling error. The offset error is regarded as the sum of all offset errors of all measuring circuit components, while the scaling error is regarded as the sum of all scaling errors of all measuring circuit components. This corresponds to the linear combination of a straight line which relates the error-containing current value to the current value which is actually present. Alternatively, the relationship may be regarded as a straight line which puts the overall measuring error component in relation to the actually flowing current or to the error-containing measured value of the current. In the latter case, the spacing of the straight lines at a current of zero corresponds to the offset error, and the slope corresponds to the scaling error.

According to the exemplary embodiments and/or exemplary methods of the present invention, offset errors and scaling errors are treated separately, and optionally are also detected and compensated for separately, the charge value supplied by the estimator and related to the time frame being used for the point in time of the detection of the two errors, and also for detecting the two errors themselves. The offset error is detected at a current of zero; a current of zero corresponds to a relative charge of zero which is supplied by the estimator. For detecting current, the estimated charge accumulated over the time window may be used as a criterion for detecting the zero crossing, or alternatively, the measured current may be used as an instantaneous value, as a time-averaged value, or in particular as a value which is integrated over the time window. Similarly, the scaling error is detected at high currents, which may be at a maximum, the relative charge value supplied by the estimator or the measured current being used for detecting the point in time of the relative maximum. In addition, for detecting the scaling error itself, the charge value supplied by the estimator is used, together with the corresponding measured current or its time integral over the time window, in order to detect the error as a difference, and to derive the correction factor therefrom.

The estimator is thus used according to the present invention for (recurring) calibration of the current measurement, additional information thus being included in the system, and the estimator providing the accumulator state based not only on the measured current, but also taking further operating parameters into account which are associated with the state of charge, and which are not associated or only indirectly associated with the accumulator current. In particular, the points in time of the detection of the offset error and scaling error are ascertained by the estimator, as well as the associated estimated current values, which are used as a calibration reference for the current values which are measured with the aid of a current sensor in order to calibrate the current sensor/the current measurement.

A model on which the error-compensated current measurement according to the present invention is based is explained below. The measured current is composed of the sum of the current measurement offset error and the actually flowing current, which is multiplied by the current measurement scaling error. Thus, instead of the time integral over the actually flowing current, the charge resulting from measurement as the sum of the integral of the offset error over the time window and the scaling error, multiplied by the integral of the actually flowing current over the time window, results for the time window. The charge, which is based on the measured error-containing current, thus results from the sum of the offset error multiplied by the length of the time window and the scaling error multiplied by the actually supplied or withdrawn charge, referred to as the relative charge, which has been transmitted during the time window in the form of the current which has actually flowed. According to this model, the offset error is assumed as the current, and the scaling error is assumed as a unitless variable, it also being possible to consider the offset error as the charge quantity which is related to the time interval, and to consider the scaling error as differential current or as differential charge.

According to the exemplary embodiments and/or exemplary methods of the present invention, for the error detection the estimated relative charge (related to a time window) is contrasted with a measured current. For this purpose, on the one hand the measured current is related to the time window by integration over same in order to allow a comparison with the estimated relative charge which is related to the time window. In principle, on the other hand a comparison is also possible by normalizing the estimated relative charge to the length of the time window by division, it being possible to compare the estimated relative charge normalized in this way to the measured current by subtraction. In the latter case, the current may be averaged over the time window.

The above consideration of the actually measured current may be adapted to this approach, in that instead of the actually measured current, the relative charge quantity actually detected for the time window may be considered, and such an integral representation is provided due to the corresponding conversion of current into charge by multiplication by the length of the time window.

To compensate for the above-described scaling error and offset error, two compensation variables may be used, for example a compensation current which corresponds to the negative value of the offset error, and a compensation factor for the scaling error which corresponds to the reciprocal value of the scaling error. If a current or a charge is used instead of a factor for the compensation of the scaling error, the current or charge may also be provided by reversing the algebraic sign of the corresponding scaling error variable. However, the underlying aspect of the present invention provides that the offset error, in whatever variable it is provided in, is separated from the scaling error so that these errors are compensated for not simultaneously, but which may be in succession, for example within an iterative process in which offset error detection and scaling error detection as well as their respective compensation are carried out in alternation or in general, in succession, for example in an alternating manner.

In particular the (one-time or multiple) compensation of the scaling error is based on a (one-time or multiple) compensation of the offset error, at least one offset error compensation preceding a scaling error detection or a scaling error compensation. This corresponds to solving a linear equation system of a straight line according to the Gaussian form. Alternatively, however, instead of solving the two types of error in a stepwise manner, another form may be selected in order to solve an equation system of a straight line having two equations with regard to scaling errors and offset errors.

The offset error may be determined for time windows in which the relative charge, or the current measured for this purpose, or its time integral over the time window, is essentially zero. The relative charge and the measured current are two variables which are to be used as an alternative to or in combination with one another in order to estimate the load state. At high load, the scaling error may be measured, and at low (or no) load the offset error may be measured. High charge or high current (i.e., values having an absolute value which is greater than a minimum value or is at least as great as the minimum value) correspond to high load, and low or no charge or current corresponds to low load, the absolute value of the current or charge values being less than or equal to a maximum value (the maximum value may essentially correspond to 0+ε).

The determination of the offset error may precede the determination of the scaling error. For a charge which is provided by the estimator and which is related to the time window, according to the present invention it is assumed that the accumulator current actually flowing is essentially zero. In this case, the constant (not current-dependent) difference between an actual current flow (zero or less than a maximum value) and a measured current (zero or less than a maximum value) is referred to as offset error, which corresponds to the current measurement offset error. This also applies to estimated charges, related to the time window, whose absolute value is below an offset error threshold value. This threshold value may correspond only to a small portion of a standard operation current flow value, for example 1%, one-tenth of a percent, or less. For an estimated charge, related to a time window, which is not equal to zero (but which is less than the threshold value), this charge may be normalized to the length of the time window, and the offset error results from the difference between the estimated charge, normalized to the length of the time window, and the detected, i.e., measured, accumulator current.

As previously noted, the estimated charge and the associated current, which results from normalizing the estimated charge to the length of the time window, may be assumed to be zero, so that the offset error corresponds to the detected accumulator current, or vice versa. The comparison of the estimated charge to the accumulator current may thus be carried out as a current comparison, either by assuming the estimated charge to be zero, or by normalizing the estimated charge to the length of the time window before the estimated charge is compared to the accumulator current. In addition, the comparison of the estimated charge to the detected accumulator current may be provided as a charge comparison, the estimated charge being compared to the detected accumulator current, which is related to the time window by multiplication by the length of the time window. The resulting difference is either used for the compensation as an offset error charge, related to the time window, or is once again normalized for the compensation to the length of the time window to provide an offset error in the form of a current.

The point in time, or the time window, at which the estimated charge is essentially zero and thus is assumed to be equal to zero, or at which the estimated charge is low, and thus includes only a very small portion of the scaling error, is referred to as the zero crossing point in time. The zero crossing point in time, or the time window in which the zero crossing occurs, may be provided by comparing the charge to an upper and a lower limit, the limits being situated around the current zero point and defining a current interval whose absolute maximum is clearly below a standard current value or clearly corresponds to a value below a maximum current value.

The standard current value refers to standard operating parameters, and the maximum current value refers to a maximum current value provided by the accumulator and the shunt resistor, the limit for detecting the zero crossing point in time corresponding to only a small fraction of this value, for example 10⁻³, 10⁻⁴, or 10⁻⁶. The comparison of the estimated charge for the zero crossing point in time to the detected accumulator current includes forming the difference between the detected accumulator current and the estimated charge, as well as the assumption that the estimated charge corresponds to zero, and therefore the detected accumulator current is associated with the offset error.

On the other hand, the scaling error is ascertained at a maximum point in time at which the portion of the offset error is as low as possible, this may be provided by compensating for the offset error prior to ascertaining the scaling error, or assuming the portion of the offset error as a predefined variable or as equal to zero. The time window may be selected in such a way that for the greatest part of the time window or for the entire time window, the measured current or the estimated relative charge, in relation to the time window, has a high value which is greater than a predefined value. For this purpose, the time window may be ended when the measured current or the estimated charge is less than the predefined value.

In addition, only time windows are used in which there is no change in the algebraic sign of the measured current or of the estimated charge. The time window spans a point in time of high load of the accumulator, whether with regard to a discharge or a charge. The maximum point in time, i.e., the time window in which this occurs, is determined by the point in time of a relative maximum of the estimated charge Qr, which is related to the time window, or relates to a point in time, i.e., a time window in which the estimated charge has a value which is greater than a minimum charge difference. The minimum charge difference, related to the time window and thus formulated as an averaged current value which reflects the estimated relative charge, corresponds, for example, to a standard current or a high proportion of a standard current or maximum current value which is provided by the accumulator and the shunt resistor. According to the present invention, the accumulator current is also compensated for based on the current measurement scaling error, for example by multiplying the detected or measured accumulator current by the reciprocal value of the scaling error.

Immediately after being computed, the offset error and the scaling error may be used completely for the compensation, i.e., used completely by subtraction (offset error) or by multiplication by the reciprocal value (scaling error) for the compensation. Alternatively, however, the errors, which may be as the proportion of errors increases, are taken into account in a continuously increasing compensation. For continuously increasing compensation, a PI controller may be used, as described in greater detail below.

The method according to the present invention for error-compensated current measurement thus includes the steps of Claim 1, which are implemented by corresponding features of a device according to the present invention. Thus, for the detection a current detection sensor is used, which may be a shunt resistor or also a magnetic sensor or a Hall sensor, whose error is linearly approximated according to the present invention by offset errors and scaling errors. The device includes a current signal input which receives a measured current signal in digital or analog form from a measuring device, for example a current detection sensor and its associated signal preprocessing circuit. The device also includes an estimator which provides the estimated charge, related to a time window, based on the model of the estimator.

The model maps multiple states, and as an approximation corresponds to the physical model of the accumulator. The model maps the accumulator based on multiple operating variables, one operating variable being the accumulator current, and further operating variables which are not, or only indirectly dependent on the accumulator current, and which have an influence on the state of charge which is estimated by the model. Such further operating variables are in particular the terminal voltage, a no-load voltage which is used during no-load operation, an internal resistance which is used within the model, the temperature of the accumulator, and others. These further operating variables may be used individually or also in any desired combination with one another, together with the accumulator current. The model is a state of charge (SOC) estimator, for example based on a plurality of diffusion processes which are represented in the form of numerical approximations. The model may also include interpolation in order to determine the accumulator state to be estimated, and in particular the state of charge or the estimated charge which is related to the time window, using discrete known operating parameters regarding various discrete states.

In addition, with the aid of empirical data, for example in the form of tables, the model may also reflect various states of the accumulator which are already known based on various operating parameters, it being possible to ascertain the closest state by comparing the instantaneous operating parameters, optionally using interpolation. The model may thus have various levels of complexity, for example in the form of complex Kalman filters or neuronal networks, which implicitly or explicitly reflect the underlying processes in detail, or may be reflected by simple models which are essentially based on empirically ascertained table entries.

For detecting the zero crossing, a zero crossing comparator is provided which ascertains whether the estimated charge essentially corresponds to zero, or the absolute value of the estimated charge is below a threshold value, i.e., a maximum value. An offset error ascertainment unit is connected to the zero crossing comparator, and provides the offset error with the aid of a subtraction unit. The subtraction unit may also be composed of a simple signal relay when the estimated charge is assumed to be zero, and thus, the estimated charge which is normalized to the time window directly reflects the offset error. This corresponds to subtracting the normalized estimated charge from zero. In addition, the device according to the present invention includes a maximum comparator which ascertains whether the estimated charge (or the measured current or the integral thereof over the time window) is sufficiently large (in comparison to a minimum charge difference). Alternatively, the maximum comparator may compare the estimated charges in successive time windows in order to recognize consecutive slopes having opposite algebraic signs, and to deduce therefrom a relative maximum of the absolute value of the estimated charge.

Thus, the estimated charges of two successive time windows may be compared in order to determine the slope, a repeated comparison of two (further) time windows representing the location of the relative maximum. Time windows following one another in direct succession may be compared. The scaling error ascertainment unit includes an offset error compensation unit, which initially subtracts the ascertained current measurement offset error from the accumulator current, for example based on an (averaged) current or based on the time integral of the estimated accumulator current. A ratio unit is then used to ascertain the scaling error by dividing the accumulator current by the estimated charge, which is normalized to the length of the time window. Alternatively, the reciprocal value thereof may be provided. As a further alternative, the accumulator current multiplied by the length of the time window, or the accumulator current integrated for the length of the time window, may be compared to the estimated charge, which is related to the time window.

For the compensation, the ascertained offset error, for example having reversed algebraic signs, is added to the (measured) accumulator current, and the scaling error as the reciprocal value thereof is multiplied by the accumulator current. This corresponds to a direct compensation.

Alternatively, however, a correction error generator may be provided which generates a correction error and corrects the detected accumulator current based on the correction error. The correction error generator may include a PI controller which uses the correction error as a feedback control variable, the current measurement offset error being used as a setpoint default, whose difference with respect to the control variable is used for integrative control. Instead of the offset error, the scaling error or a sum of the offset error and the scaling error may be predefined as the setpoint value.

In another configuration, the device includes two correction error generators, one correction error generator being used for the offset error, and the other correction error generator being used for the scaling error, both correction error generators including a PI controller which receives the offset error or the scaling error as the setpoint value, and uses the particular correction error as a control variable. The compensation is then carried out by combining the correction errors, or by individually compensating for the offset error and the scaling error based on the associated offset error correction error or scaling error correction error, in order to correct the two errors in combined form. The PI controller(s) is/are part of a compensation unit of the device, each PI controller including an amplifier stage (P), an integrator stage (I), an error formation unit, and a feedback path.

The device also may include a time window generator which specifies the start and end of the time window, the time windows may be following one another in direct succession. In order to suitably provide the time window, the time window generator may evaluate the measured current or the estimated relative charge to determine whether the requirements necessary for detecting the offset error or the scaling error are met. A requirement for detecting the scaling error is the detection of a high accumulator load, and a requirement for detecting the offset error is the detection of a low accumulator load. A high accumulator load is detected, for example, by comparing the measured current value or the estimated relative charge to a minimum value or by detecting relative minima of these variables, and a small average accumulator load, i.e., which is integrated or summed over the time window, is detected, for example, by comparing the measured current value or the estimated relative charge to a maximum value, or by detecting a zero crossing or a value which essentially corresponds to zero.

The device also may include a normalizer which normalizes the estimated charge to the length of the time windows by a visual arrangement, or which relates the accumulator current to the time window by multiplication by the length of the time window. In addition, components of the device are connected to the time window generator in order to detect the start and end of each time window, so that a time window for which the charge, related to the time window, clearly deviates from zero or is not sufficiently large is excluded from the ascertainment of the offset error or from the ascertainment of the scaling error. The length of the time windows may be 30 s-1800 s, 60 s-1500 s, 100 s-1000 s, or 500 s-900 s, it being possible for time windows directly or indirectly following one another to have identical lengths or different lengths. The start and the end of the time windows may be selected according to the above-described requirements for detecting offset errors and scaling errors. This also applies for the steps of the method according to the present invention. The time windows may be ended, for example, when the estimated charge clearly deviates from zero after a zero crossing point in time is detected, or the absolute value of the estimated charge drops below a minimum charge difference after a maximum point in time is detected.

Between the compensation and the detection of the offset error, of the scaling error, or of both errors, these may be compensated for according to a temperature or a change in temperature. For this purpose, a temperature error component is ascertained for the offset error, for the scaling error, or for both errors as a linear function of the temperature or a temperature difference. The linear dependency is predetermined by a temperature characteristic of at least one component of the measuring device, for example as a function of the temperature characteristic—which is approximated to a straight line—of the resistance value of the shunt resistor, of the offset error, or of the scaling error of the buffer stage (provided by an operational amplifier, for example), by the scaling error on the basis of the temperature dependency of a timer of a sample-and-hold device, or on the basis of the temperature drift of a reference voltage source of an A/D converter. The temperature error component corresponds to the extrapolated temperature error which is added to the particular error or combination of errors in order to also compensate for the temperature error component during the compensation.

According to the exemplary embodiments and/or exemplary methods of the present invention, dependencies, even those which are constant in sections, in the form of successive temperature intervals are regarded as a linear dependency, while one temperature error component value is regarded as constant. The compensation is used in particular for the temperature dependency of the current measurement offset error.

The compensation may be provided, for example, by an interpolator of the device according to the present invention, which, based on temperatures of the current detection sensor or other components of the current measuring device, provides a temperature error component by interpolation. The temperature dependency may be represented by a slope or a slope line which reflects a linear dependency. In principle, however, higher-order approximations may also be used for ascertaining the temperature error component. The approximations may be represented as discrete values or value intervals, interpolation points defining the curve by interpolation. For this purpose tables may be used, which may be containing an associated interpolation. In addition, the temperature dependency may be implemented as an approximation formula whose parameters reflect the material characteristics in a continuous dependency, the approximation formula reflecting a linear dependency or also higher-order dependencies.

The temperature detected at the shunt resistor may be used as the temperature; alternatively, the temperature of the accumulator or of the measuring signal preprocessing circuit connected to the shunt resistor may be used. For this purpose, additional temperature sensors may be used, or a temperature sensor of the accumulator may be used. The temperature compensation is based on a temperature difference between a temperature which was detected during the time window and a temperature which prevails during the compensation. The device thus also may include a memory which stores the temperature values which are obtained as described above. The same memory or another memory may be used for this purpose in order to store the current measurement offset error, at least until a maximum point in time has occurred, at which the previously detected offset error may be accessed during ascertainment of the scaling error and the associated compensation.

The method according to the present invention also may include the step of ascertaining the actual state of charge of the accumulator as a time integral, as a cumulative total of the compensated accumulator current, as a cumulative total of the estimated charge, or as a combination thereof. In addition, the device may include an integrator or a summer which, as the result, outputs the actual state of charge of the accumulator and obtains the compensated measured accumulator current or the estimated charge, or a combination thereof.

The device may be implemented by a programmable circuit in which individual software components of the device together with the processing hardware are provided. Alternatively, individual components or all components of the device may be designed as a circuit.

Exemplary embodiments of the present invention are illustrated in the drawings and explained in greater detail in the following description.

### BRIEF DESCRIPTION OF THE DRAWINGS

FIG. 1 shows an accumulator current measuring device for carrying out the present invention.

FIG. 2 shows a circuit diagram of the device according to the present invention for a more detailed explanation of the method according to the present invention.

### DETAILED DESCRIPTION

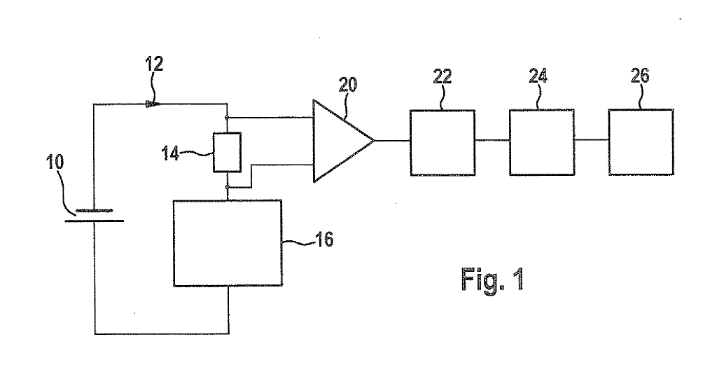

FIG. 1 shows an accumulator 10, which generates current 12 which flows through a shunt resistor 14 and a consumer 16. Accumulator 10, shunt resistor 12, and consumer 16 form a closed circuit. Instead of shunt resistor 10, a continuous line may be used, a Hall sensor or some other magnetic sensor detecting the magnetic field generated by current 12 and deducing current 12 therefrom. The dropping voltage at the shunt resistor 14 is supplied to a buffer circuit 20, which has a high internal resistance and optionally amplifies the voltage signal. The output of the buffer circuit is connected to a sample-and-hold stage 22, which samples and holds the analog value supplied by buffer circuit 20, and relays same to an A/D converter 24, which generates a digital value from the analog signal and supplies the digital value to microcontroller 26 for further processing. Elements 20, 22, 24 and optionally also 26 are elements of a signal preprocessing circuit, each of which introduces errors into the measurement. Thus, the buffer circuit includes an operational amplifier having an offset error (and optionally also a scaling error), and A/D converter 24 includes a reference voltage source, for example a reference voltage semiconductor, which has a scaling error when the temperature changes, it also being possible for sample-and-hold stage 22 to optionally introduce an offset error or scaling error. In addition to the temperature dependency, offset errors and scaling errors may result from component tolerances, for example from a 5% or 3% tolerance of the shunt resistor. Additional errors result from the temperature difference between the manufacturing site and the location of use; during manufacture the system has optionally been calibrated or at least has a slight error, and at the location of use, for example in the engine compartment of a motor vehicle, a higher temperature prevails, resulting in additional errors.

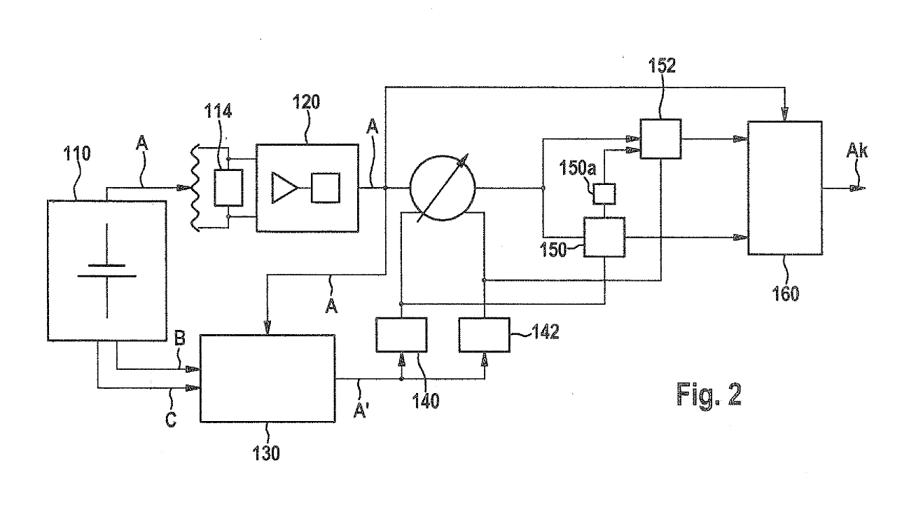

FIG. 2 shows a device according to the present invention together with an accumulator 110 which has operating parameters, which are transmitted to a shunt resistor 114 and an estimator 130. The operating parameters of the accumulator are denoted by reference characters A, B, and C, since they are essentially interchangeable (except for the accumulator current and the terminal voltage), provided that they correlate with the state of charge of the accumulator. The operating variables in FIG. 2 are accumulator current A, temperature B, and terminal voltage C. Current A is supplied in preprocessed form by the shunt resistor and a signal preprocessing circuit 120 connected thereto, to estimator 130.

Thus, the device includes two lines for ascertaining the accumulator current: line 114, 120, based on the measurement, which generates an error-containing measuring current, and the line of estimator 130, which on the basis of measured current A and further operating parameters B, C estimates a state from which the estimator deduces an estimated charge A′. Estimated charge A′ relates to a specific time interval, and therefore, the same as the physical unit current, is related to time. For this reason, measured instantaneous current A is denoted similarly to estimated charge A′. Instead of reference character A, reference character Qr is also used to denote a relative charge (Qr), and instead of reference character A′, the accumulator current is denoted by reference character Im, which stands for a measured current (I). Estimator 130 thus outputs an estimated charge Qr and transmits same to comparators 140, 142 connected thereto. As a zero crossing comparator, comparator 140 ascertains whether estimated charge A′ (Qr) is essentially zero (or, alternatively, starting from an absolute value, whether the estimated charge is less than a minimum value).

Thus, comparator 140 compares to zero or to interval limits which define a narrow interval around the zero point. The zero crossing comparator thus ascertains a zero crossing point in time. Similarly, comparator 142, which represents a maximum comparator, compares the absolute value of estimated charge A′ (Qr) to a minimum charge difference, or, in another embodiment, detects the relative maximum of time window-related estimated charge A′ by comparing estimated charges of different time windows. Maximum comparator 142 may also carry out both comparisons, and may output that a maximum occurs only when on the one hand a relative maximum has been recognized by comparator 142, and on the other hand, the value of this maximum of the estimated charge is greater than a minimum charge difference. The minimum charge difference thus provides a threshold value for the estimated charge which indicates that the estimated charge is sufficiently large for scaling error detection, the minimum charge difference representing a difference between various overall states of charge of the accumulator.

Comparator 140 and comparator 142 are each connected to a symbolically illustrated measuring value detector which ascertains the particular value of the estimated charge when the point in time of the zero crossing is identified and the point in time of the scaling error detection is identified. These values of the estimated charge are transmitted to an offset error ascertainment unit 150 or to a scaling error ascertainment unit 152 in order to compute the particular error, and thus allow a compensation. Device 150 initially ascertains the offset error and stores same, for example, in a memory 150a associated with offset error ascertainment unit 150. If at a later point in time a point in time for scaling error detection occurs, device 152 generates the scaling error, based on the scaling error stored in memory 150a and the estimated charge at the point in time of the scaling error detection.

The point in time of the scaling error detection corresponds to the point in time at which the maximum comparator ascertains a sufficiently large estimated charge or ascertains a relative maximum of the absolute value of the estimated charge (or both), the point in time of the scaling error detection being equivalent to the time window in which the sufficiently large estimated charge, the relative maximum of the estimated charge, or both occur(s). Similarly, the zero crossing point in time corresponds to the time window in which the zero crossing occurs. The associated absolute value is the average value of the estimated charge for the entire time window, or, if only one charge value is estimated during this time window, is the estimated charge value associated with the time window.

Lastly, the device in FIG. 2 includes a compensation unit 160 which receives measured accumulator current A (Im) as well as the scaling error, in addition to the offset error from devices 150 and 152. Based on the known error, compensation unit 160 compensates for measured current A (Im) and outputs compensated measured current value Ak.

In the case of further temperature compensation, compensation unit 160 is connected to temperature sensors of accumulator 110, of shunt resistor 114 (or of current sensor 114), and of signal preprocessing circuit 120 in order to ascertain additional temperature error components of the offset error and of the scaling error in the event of temperature increases. The temperature error components thus ascertained are combined with the offset error or with the scaling error, the error compensation being carried out based on the combined errors. In one alternative embodiment, the directly ascertained offset error and scaling error are initially compensated for, the associated temperature error components being taken into account in the compensation in a subsequent step or a preceding step. In order to associate the various temperatures with the related time windows, compensation unit 160 also may include a time signal input that emits time signals which allow ascertained scaling errors or offset errors to be associated with particular temperatures (at the same time).

The lines illustrated in FIG. 2 correspond to signal transmission connections, which in the case of a software implementation are realized by a corresponding procedure or function headers and their transfer variables. The arrows indicate the direction of the information flow or the signal flow. Except for the connection between accumulator 110 and shunt resistor 114, all connections transmit signals which reflect the values of physical variables.

The device according to the present invention optionally includes an integrator which is connected to the current signal input and which is set up for integrating accumulator current (Im) for the duration of the time window in order to carry out the comparison with the relative charge of the estimator, based on a charge comparison. In addition, the device may include a time normalizer which transmits the time window-related charge (whether from the estimator or from the integrator) to a unit time basis which is different from the time window, for example 1 second, in order to carry out the comparison between the estimation and the measurement on the basis of the ampere unit.

1-10. (canceled)

11. A method for providing error-compensated current measurement of an electrical accumulator, the method comprising:
providing a time window-related estimated charge, which is ascertained by a model-based estimator from operating variables of the accumulator and which reflects the estimated charge that has been withdrawn from the accumulator and has been supplied to the accumulator within the time window;
detecting the accumulator current supplied to the accumulator and withdrawn from the accumulator during the time window, with a current detection sensor;
detecting a zero crossing point in time at which the absolute value of the estimated charge or the accumulator current is less than a maximum value;
detecting a maximum point in time at which the absolute value of the estimated charge or the accumulator current essentially has a relative maximum or has a value which is greater than a minimum value;
ascertaining a current measurement offset error at the zero crossing point in time by comparing the estimated charge to the detected accumulator current;
compensating for the accumulator current according to the current measurement offset error;
ascertaining a current measuring scaling error at the maximum point in time by comparing the estimated charge to the detected accumulator current;
subtracting the ascertained current measurement offset error from the comparison result thus obtained; and
compensating for the accumulator current based on the current measurement scaling error.

12. The method of claim 11, wherein the estimated charge is provided by ascertaining the estimated charge using an estimator which includes a physical model of the accumulator, the operating variables of the accumulator including the accumulator current and at least one further operating variable of the accumulator which is not directly dependent on the detected accumulator current and which influences the estimated charge, the at least one further operating variable including an accumulator terminal voltage, an accumulator temperature, at least one further operating variable of the accumulator which is different from the accumulator current, or a combination thereof.

13. The method of claim 11, wherein at least one of the compensation of the current measurement scaling error and the compensation of the current measurement offset error includes:
detecting a temperature of the current detection sensor or a temperature of an accumulator current measuring device which is connected to the current detection sensor;
ascertaining a temperature error component for the current measurement offset error and for the current measurement scaling error as a linear function of the temperature, the linear dependency being predetermined by a temperature characteristic of at least one component of the accumulator current measuring device, which includes the current detection sensor and detects the accumulator current; and
adding the particular temperature error component to the current measurement offset error and to the current measurement scaling error.

14. The method of claim 11, wherein the compensation includes one of:
subtracting the current measurement offset error, the current measurement scaling error, or both errors from the accumulator current;
multiplying a reciprocal value of the current measurement offset error, a reciprocal value of the current measurement scaling error, or a reciprocal value of both errors by the accumulator current; and
providing a correction error on the basis of which the detected accumulator current is corrected, the correction error being used as a control variable of a PI controller which has the current measurement offset error, the current measurement scaling error, or a sum thereof as the setpoint value, to continuously advance the correction error to the current measurement offset error, the current measurement scaling error, or a combination of both errors, according to the control response of the PI controller, the accumulator current being corrected according to the correction error provided by the PI controller.

15. The method of claim 11, wherein providing the estimated charge includes:
providing the time window as one of a plurality of successive or contiguous time windows, either all time windows having an associated length and the estimated charge being normalized to the associated length, or not being normalized, or time windows of the plurality of time windows of various lengths and the estimated charge being normalized to the particular length of the associated time window, and in addition, during the entire time window either the estimated charge or the measured accumulator current is essentially zero, the absolute value of the estimated charge or the measured accumulator current essentially has a relative maximum or a value which is greater than a minimum value, or the estimated charge which is linked to the time window is not used either for ascertaining the current measurement offset error or for ascertaining the current measurement scaling error.

16. A device for providing error-compensated current measurement of an electrical accumulator, comprising:
a model-based estimator configured to provide an estimated charge which is related to a time window, and which is connected to the operating variable input;
a current signal input configured for connection to an accumulator current measuring device which outputs a current signal which represents the accumulator current during the time window, which is supplied to the accumulator and is withdrawn from the accumulator;
an operating variable input for at least one operating variable of the accumulator;
a zero crossing comparator, connected to the estimator, which compares the estimated charge or the accumulator current to a maximum value in order to ascertain a zero crossing point in time;
a maximum comparator, connected to the estimator, which compares the absolute value of the estimated charge or the accumulator current to a minimum value, or which compares estimated charges or detected accumulator currents of two, three, or more than three successive time windows to one another to determine a point in time of a scaling error detection based on the difference;
an offset error ascertainment unit which includes an offset error subtraction unit which is configured to subtract the estimated charge, provided by the estimator, from the accumulator current at the zero crossing point in time which is provided by the zero crossing comparator, to provide the current measurement offset error as the result of the subtraction;
a scaling error ascertainment unit which includes an offset error subtraction unit which is configured to subtract the current measurement offset error, provided by the offset error ascertainment unit, from the accumulator current or from the time integral of the accumulator current to compensate for the offset error of the accumulator current, the scaling error ascertainment unit also including a ratio unit which is configured to provide a ratio of the compensated accumulator current to the estimated charge as the scaling error; and
a compensation unit configured to compensate for the provided offset error of the accumulator current, and to compensate for the scaling error of the accumulator current which has been compensated for with regard to the offset error.

17. The device of claim 16, wherein the estimator includes a physical model of the accumulator, the operating variable input being configured to receive an accumulator terminal voltage, an accumulator temperature, at least one further operating variable of the accumulator which is different from the accumulator current, or a combination thereof, the operating variable not being directly dependent on the detected accumulator current, and which influences the estimated charge.

18. The device of claim 16, further comprising:
an interpolator and a temperature input connected thereto for temperatures of the current detection sensor or an accumulator current-measuring device which is connected to the current detection sensor, the interpolator interpolating a temperature error component of the provided offset error, of the provided scaling error, or of both errors, according to a predetermined linear temperature characteristic, provided by the interpolator, of at least one component of the accumulator current measuring device, which includes the current detection sensor, the interpolator being configured to add the particular temperature error component to the current measurement offset error, to the current measurement scaling error, or to both errors for additional temperature compensation.

19. The device of claim 16, wherein the compensation unit includes one of:
a subtraction unit configured to subtract the current measurement offset error, the current measurement scaling error, or both errors from the accumulator current;
a multiplication unit configured to multiply a reciprocal value of the current measurement offset error, a reciprocal value of the current measurement scaling error, or a reciprocal value of both errors by the accumulator current; and
a correction error generator configured to generate a correction error and to correct the detected accumulator current based on the correction error, the correction error generator including a PI controller which uses the correction error as a control variable, and the PI controller receives the current measurement offset error, the current measurement scaling error, or a sum thereof as the setpoint value, and has a control response according to which the correction error is continuously advanced to the current measurement offset error, to the current measurement scaling error, or to a combination of both errors, and the compensation unit is configured to correct the accumulator current according to the correction error which is provided according to the correction error generator.

20. The device of claim 16, further comprising:
a time window generator which sets a start and an end of the time window, the start of a directly subsequent time window coinciding with the end of the preceding time interval or following same, and all time windows having the same length or having different lengths, and the device including a normalizer which is configured to normalize the estimated charge to the length of the time window or to 1 for time windows of the same length, and is configured for time windows of different lengths to normalize the estimated charge to the length of the time window, the time window generator being set up so that the offset error ascertainment unit, the scaling error ascertainment unit, the compensation unit, or a combination thereof is/are connected to the time window generator, and ascertaining, subtracting, or compensating for the offset error only when the zero crossing comparator ascertains that the absolute value of the estimated charge or of the accumulator current is less than a maximum value for the entire duration of the time window, or at least one of the scaling error ascertainment unit and the compensation unit being connected to the time window generator, and ascertaining or compensating for the scaling error only when the maximum comparator ascertains an absolute value of the estimated charge or of the accumulator current which is greater than the provided minimum value for the entire duration of the time window, or when the point in time of the scaling error detection is within the time window.
